(19) United States
(12) Patent Application Publication
(10) Pub. No.: US 2026/0160800 A1
(43) Pub. Date: Jun. 11, 2026

(54) TEST EQUIPMENT, METHOD AND COMPUTER READABLE STORAGE MEDIUM

(71) Applicant: Nuvoton Technology Corporation, Hsinchu Science Park (TW)

(72) Inventor: Tse-Yu LIN, Taichung City (TW)

(21) Appl. No.: 19/408,889

(22) Filed: Dec. 4, 2025

(30) Foreign Application Priority Data
Dec. 10, 2024 (TW) 113147768

(51) Int. Cl. G01R 31/28

(52) U.S. Cl. CPC G01R 31/2831

(57) ABSTRACT

A test method is provided. In a training period, a plurality of WAT sample data of a plurality of sample wafers are received, and a CP operation is performed on the sample wafers to generate a plurality of CP sample data. The machine learning model calculates the WAT sample data and the CP sample data to generate a correlation. In a test period, the product information and the WAT measurement data of a wafer to be tested are input to the machine learning model. The machine learning model determines at least one key parameter from the WAT measurement data according to the correlation. The machine learning model adjusts the testing sequence of a plurality of test items according to the key parameter. The wafer to be tested is tested according to the adjusted testing sequence of the plurality of test items.

### CROSS REFERENCE TO RELATED APPLICATIONS

This Application claims priority of Taiwan Patent Application No. 113147768, filed on Dec. 10, 2024, the entirety of which is incorporated by reference herein.

### TECHNICAL FIELD

The present disclosure relates to a test method, and, in particular, it relates to a test method for testing wafers according to an optimal testing sequence.

### BACKGROUND

During the process of manufacturing wafers, defects may arise due to various factors (such as insufficient doping concentration, or a short circuit in the metal layer). Therefore, before they are sealed, the dies on these wafers must be tested. However, there are a large number of dies on each wafer, and there are many test items. Therefore, each wafer requires a lot of testing time.

### BRIEF SUMMARY

An embodiment of the present disclosure provides a test equipment comprising a storage circuit, an input-output interface, and a calculation circuit. The storage circuit stores a machine learning model. The input-output interface receives a plurality of wafer acceptance test (WAT) sample data and a plurality of chip probing (CP) sample data. The calculation circuit accesses the storage circuit to load the machine learning model. In a training period, the calculation circuit provides the WAT sample data and the CP sample data to the machine learning model, and the machine learning model calculates the WAT sample data and the CP sample data to generate a correlation. In a test period, the input-output interface receives product information and WAT measurement data, the calculation circuit inputs the product information and the WAT measurement data to the machine learning model, and the machine learning model adjusts the testing sequence of a plurality of test items in a CP operation according to the correlation.

An embodiment of the present disclosure provides a computer readable storage media storing a program code. In response to the program code being executed, the following steps are implemented. A plurality of WAT sample data from a plurality of sample wafers are received. A CP operation is performed on the sample wafers to generate a plurality of CP sample data. The WAT sample data and the CP sample data are input into a machine learning model in a training period. The machine learning model calculates the WAT sample data and the CP sample data to generate a correlation. In a test period, the product information and the WAT measurement data of a wafer to be tested are input into the machine learning model. The machine learning model determines at least one key parameter from the WAT measurement data according to the correlation. The machine learning model adjusts the testing sequence of a plurality of test items according to the key parameter. The wafer to be tested is tested according to the adjusted testing sequence of the test items.

A test method is provided. An exemplary embodiment of a test method is described in the following paragraph. In a training period, a plurality of WAT sample data of a plurality of sample wafers are received. In the training period, a CP operation is performed on the sample wafers to generate a plurality of CP sample data. In the training period, the WAT sample data and the CP sample data are input into a machine learning model. The machine learning model calculates the WAT sample data and the CP sample data to generate a correlation. In a test period, the product information and the WAT measurement data of a wafer to be tested are input to the machine learning model. The machine learning model determines at least one key parameter from the WAT measurement data according to the correlation. The machine learning model adjusts the testing sequence of a plurality of test items according to the key parameter. The wafer to be tested is tested according to the adjusted testing sequence of the test items.

The test method may be practiced by the systems which have hardware or firmware capable of performing particular functions and may take the form of program code embodied in a tangible media. When the program code is loaded into and executed by an electronic device, a processor, a computer or a machine, the electronic device, the processor, the computer or the machine becomes a test equipment for practicing the disclosed method.

### BRIEF DESCRIPTION OF THE DRAWINGS

The present disclosure can be more fully understood by reading the subsequent detailed description and examples with references made to the accompanying drawings, wherein:

FIG. 1 is a flowchart of a test method in accordance with an embodiment of the present disclosure;

FIG. 2A is a schematic diagram of test items for a chip probing (CP) operation;

FIG. 2B is another schematic diagram of test items for the CP operation;

FIG. 2C is another schematic diagram of test items for the CP operation; and

FIG. 3 is a schematic diagram of an exemplary embodiment of a test equipment according to various aspects of the present disclosure.

### DETAILED DESCRIPTION

The present disclosure will be described with respect to particular embodiments and with reference to certain drawings, but the disclosure is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the present disclosure.

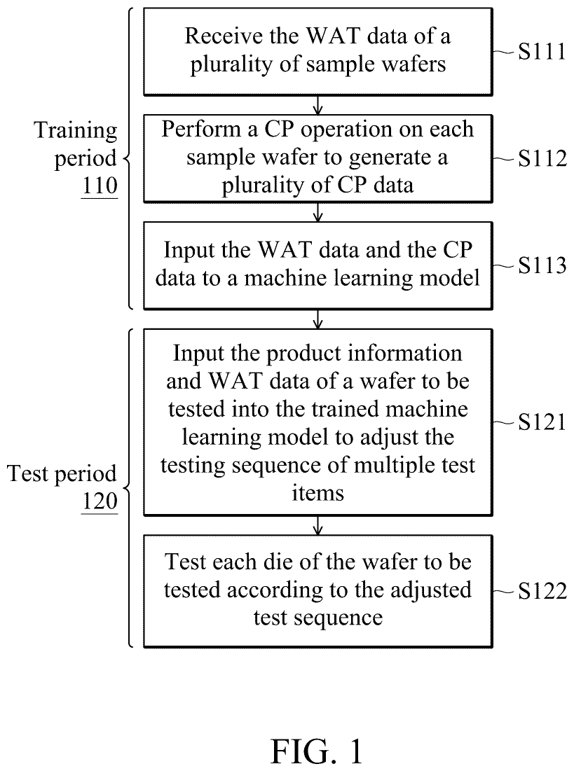

FIG. 1 is a flowchart of a test method in accordance with an embodiment of the present disclosure. The test method of the present disclosure adjusts the testing sequence of test items of a chip probing (CP) operation according to the wafer acceptance test (WAT) data of each wafer to be tested, and performs a CP operation on each wafer to be tested according to the adjusted testing sequence. In one embodiment, the most sensitive test items are tested first. Once any die of the wafer to be tested fails to pass the sensitive test items arranged in the front, the test equipment no longer spends time performing the remaining test items on the die, thereby saving testing manpower and time. The test method of the present disclosure may be implemented by a program code. The program code may be stored in a computer readable storage medium. When the program code of the computer readable storage medium is loaded and executed by a machine, the machine becomes a test equipment for implementing the test method.

In the training period 110, WAT data of a plurality of sample wafers is received (step S111). In one embodiment, the WAT data is provided by a wafer foundry. The wafer foundry performs a plurality of tests on each sample wafer and uses the test results as the WAT data. For brevity, the WAT data of the sample wafer is referred to as WAT sample data.

Next, a CP operation is performed on each sample wafer to generate a plurality of CP data (step S112). In one embodiment, if step S111 receives WAT sample data of 25 sample wafers, step S112 performs a CP operation on all dies of each of the 25 sample wafers to obtain 25 pieces of CP sample data (also referred to as raw data). Each piece of CP data records all test results of dies of a corresponding sample wafer. For example, assume that each wafer has 10,000 dies and the CP operation has 100 test items. In this case, each piece of CP data has 1 million (10,000*100) test results. For brevity, the CP data of the sample wafer is referred to as CP sample data. In one embodiment, each CP sample data contains map data, file data (also referred to as a data-log), or both.

The WAT sample data and the CP sample data are input into a machine learning model (step S113). The machine learning model calculates the WAT sample data and the CP sample data to generate a correlation. In one embodiment, the machine learning model establishes a correlation according to the WAT sample data and the failed test results in the CP sample data. For example, when a specific parameter in the WAT sample data (such as the saturation current Isat of the transistor) is not within a normal range, the test result of a specific test item (such as the on-resistance R) in the CP sample data is abnormal. In this example, since the specific test item (such as the on-resistance R) is easily affected by the specific parameter (such as Isat), the machine learning model establishes a correlation between the specific test item (such as the on-resistance R) and the specific parameter (such as Isat). The key parameter that is most likely to cause the test item to fail can be found in the WAT sample data according to the correlation established by the machine learning model.

In a test period 120, product information and WAT data of a wafer to be tested are input to the trained machine learning model to adjust the testing sequence of multiple test items (step S121). In one embodiment, the trained machine learning model determines the multiple test items required for the wafer to be tested according to the product information of the wafer to be tested. Then, the machine learning model finds the most critical parameter from the WAT data of the wafer to be tested according to the correlation in step S113, and finds at least one test item (or referred to as a sensitive test item) corresponding to the most critical parameter from the multiple test items. The machine learning model adjusts the execution time of the sensitive test item.

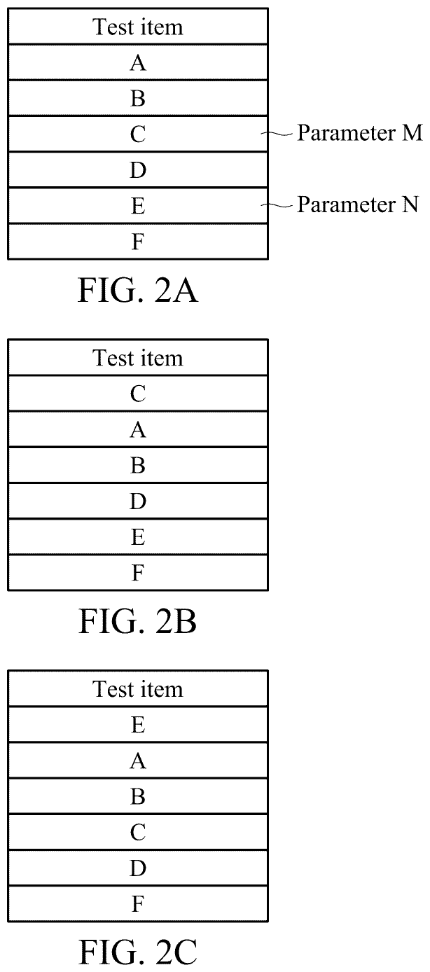

FIG. 2A is a schematic diagram of test items for a CP operation. For brevity, FIG. 2A shows test items A˜F, but this disclosure is not limited thereto. In other embodiments, the CP operation may have a different number of test items. Furthermore, the CP operation in FIG. 2A is specific to a specific product. The CP operation may have different test items for different products. For example, the CP operation may have 100 test items for a first product, and the CP operation may have 150 test items for a second product. In this case, at least one of the 100 test items for the first product may be the same as one or more of the 150 test items for the second product.

Referring to FIG. 2A, assume that during the training period 110, the machine learning model uses the WAT sample data and the CP sample data of a plurality of sample wafers to determines that the test result of the test item C is typically a failed test item when the parameter M is not within a normal range, and the test result of the test item E is typically a failed test item when the parameter N is not within another normal range. Therefore, the machine learning model generates a link between the parameter M and the test item C, and a link between the parameter N and the test item E.

Referring to FIG. 2B, in the test period, the machine learning model determines whether the parameters M and N of the WAT data of a first wafer to be tested are respectively within a first normal range and a second normal range. Assume that the parameter M of the WAT data of the first wafer to be tested is not respectively within a first normal range and a second normal range. In this case, since the test item C is most susceptible to the parameter M, the machine learning model moves the test item C before the test item A. As shown in FIG. 2B, the testing sequence of test items for the CP operation of the first wafer to be tested is C, A, B, and D˜F. FIG. 2B is another schematic diagram of test items for the CP operation.

In another embodiment, assume that the parameter N of the WAT data of a second wafer to be tested is not within a normal range. In this case, since the test item E is most susceptible to the parameter N, the machine learning model moves the test item E before the test item A. As shown in FIG. 2C, the testing sequence of test items in the CP operation of the second wafer to be tested is E, A˜D, and F. For brevity, the WAT data of the wafer to be tested is referred to as WAT measurement data.

Next, each die of the wafer to be tested is tested according to the adjusted test sequence (step S122). In one embodiment, step S122 is performed to convert the adjusted test sequence into a program code. In this case, a processing circuit (such as a CPU) executes the program code to perform CP operations on the wafer to be tested.

Taking FIG. 2B as an example, the machine learning model adjusts the testing sequence of the test items in the CP operation according to the different WAT measurement data of different wafers to be tested. The machine learning model places the most sensitive test item at the top of all other test items. Therefore, when performing the CP operation, the most sensitive test item is first performed on each die. If a die cannot pass the most sensitive test item, other test items are not performed on the abnormal die. Therefore, test time reduction can be achieved, and test efficiency is improved.

In some embodiments, when any die of a wafer to be tested cannot pass any test item of the CP operation, a test equipment marks (highlights) the die. Therefore, after completing the CP operation, the tester can know the location of the abnormal die and the yield of the wafer to be tested according to the report of the test equipment. In another embodiment, when a die of the wafer to be tested passes all test items of the CP operation, the CP operation is continued on the next die.

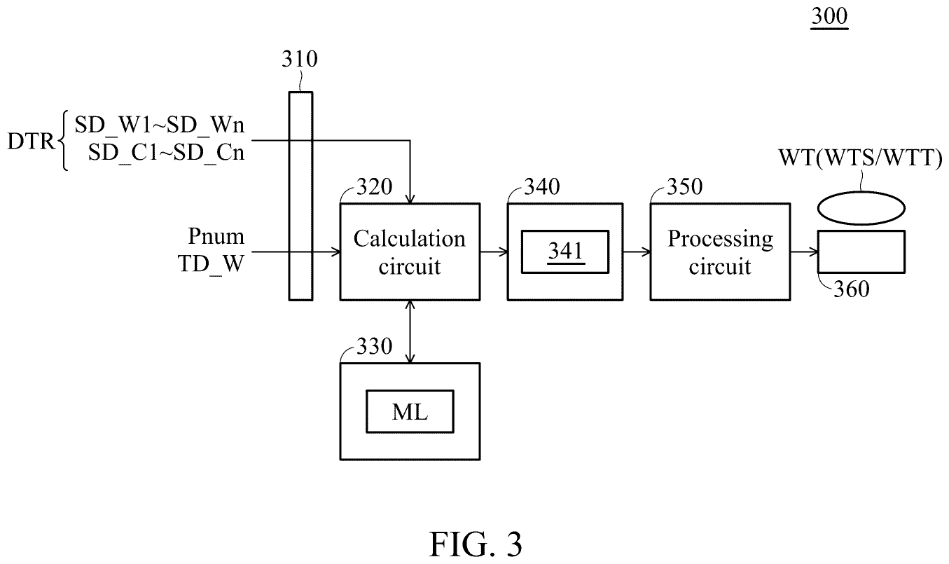

FIG. 3 is a schematic diagram of an exemplary embodiment of a test equipment according to various aspects of the present disclosure. As shown in FIG. 3, the test equipment 300 comprises an input-output interface 310, a calculation circuit 320, and a storage circuit 330. The storage circuit 330 stores a machine learning model ML. In one embodiment, the storage circuit 330 comprises a non-volatile memory for storing the machine learning model ML.

The calculation circuit 320 accesses the storage circuit 330 to load the machine learning model ML. During a training period, the input-output interface 310 receives the training data DTR. The calculation circuit 320 receives the training data DTR via the input-output interface 310 and inputs the training data DTR to the machine learning model ML to train the machine learning model ML to arrange the testing sequence of test items for CP operation. In one embodiment, the machine learning model ML calculates the training data DTR to establish a correlation. In some embodiments, the calculation circuit 320 writes the trained machine learning model ML back to the storage circuit 330.

In one embodiment, the training data DTR has the WAT sample data SD_W1˜SD_Wn of a plurality of sample wafers and the CP sample data SD_C1˜SD_Cn of each sample wafer. In another embodiment, the test equipment 300 further comprises a storage circuit 340, a processing circuit 350, and a test platform 360. The storage circuit 340 is used to store a program code 341. The test platform 360 is used to place the wafer WT. During a training period, the wafer WT serves as a sample wafer WTS. During a test period, the wafer WT serves as a wafer WTT to be tested.

The processing circuit 350 executes the program code 341 to perform a CP operation on each die of the wafer WT on the test platform 360. The CP operation has multiple test items. During the test period, the processing circuit 350 performs multiple tests on each die of the sample wafer WTS and records the multiple test results of each die. The processing circuit 350 uses all the test results of all the dies of each sample wafer WTS as a piece of CP sample data. In some embodiments, the CP sample data contains map data, a data-log, or both.

In one embodiment, the processing circuit 350 outputs the CP sample data to an external device. During the training period, the external device provides the CP sample data to the input-output interface 310. In another embodiment, the processing circuit 350 stores the CP sample data in the storage circuit 330 or 340. In this case, during the training period, the calculation circuit 320 reads the CP sample data from the storage circuit 330 or 340.

In some embodiments, the processing circuit 350 performs a CP operation on a plurality of sample wafers WTS to generate a plurality of CP sample data. During the training period, the machine learning model ML identifies failed test items according to the CP sample data, and then identifies key parameters related to the failed test items from the WAT sample data of the sample wafers WTS. The machine learning model ML establishes a correlation between the failed test items and the key parameters. The machine learning model ML determines the most sensitive test items according to the key parameters, and rearranges the testing sequence of the test items. In one embodiment, the machine learning model ML converts the testing sequence of the test items into a program code and uses the program code to replace the program code 341 in the storage circuit 340.

During a test period, the input-output interface 310 receives the product information Pnum and the WAT measurement data TD_W of a wafer WTT to be tested. The calculation circuit 320 accesses the storage circuit 330 to load the trained machine learning model ML. The calculation circuit 320 inputs the product information Pnum and the WAT measurement data TD_W into the trained machine learning model ML. The trained machine learning model ML determines which test items need to be performed on the wafer to be tested during the CP operation according to the product information Pnum. For example, when the wafer WTT to be tested is the first product, the machine learning model ML plans 100 test items, and when the wafer WTT to be tested is the second product, the machine learning model ML plans 150 test items. In one embodiment, the product information Pnum is a company product model code. In another embodiment, the product information Pnum has the company product model code and a lot number serial number, and the lot number serial number corresponds to the WAT data and the CP data of each batch of wafers.

Next, the trained machine learning model ML determines whether the WAT measurement data TD_W has a key parameter (a parameter that is most likely to cause a failed test item) according to the correlation generated by the previous training, and adjusts the testing sequence of the test items according to the judgment result. For example, when the WAT measurement data TD_W does not have a key parameter, the machine learning model ML adjusts the testing sequence of the test items according to a predetermined sequence. However, when the WAT measurement data TD_W has a key parameter (such as the parameter M in FIG. 2B), the trained machine learning model ML does not arrange the testing sequence of the test items according to the predetermined sequence. At this time, the trained machine learning model ML finds the sensitive test item (such as the test item C in FIG. 2B) corresponding to the key parameter from the multiple test items, and moves the sensitive test item (C) to the top, and arranges other test items (such as test items A, B, D˜F in FIG. 2B) after the sensitive test item (C).

In one embodiment, the calculation circuit 320 converts the test sequence adjusted by the machine learning model ML into a program code and uses the program code to update the program code 341. In this case, the processing circuit 350 performs a CP operation on the wafer WTT to be tested according to the updated program code 341. At this time, the processing circuit 350 tests each die on the wafer WTT to be tested according to the test sequence (e.g., C, A, B, D-F in FIG. 2B) arranged by the machine learning model ML.

The correlation established in advance by the machine learning model ML is used so that the machine learning model ML can determine which test items the wafer WTT is most sensitive to according to the product information Pnum of the wafer WTT to be tested and the WAT measurement data TD_W. The machine learning model ML arranges the most sensitive test items at the front. The processing circuit 350 tests each die of the wafer WTT to be tested according to the test sequence arranged by the machine learning model ML.

When a first die of the wafer WTT to be tested cannot pass one of the test items, the processing circuit 350 stops performing the remaining test items on the first die and marks the first die. In some embodiments, the first die may be marked as a defective product. In other embodiments, the tester can determine the yield of the wafer WTT to be tested according to the number of marked dies.

In another embodiment, when a second die of the wafer WTT to be tested passes all test items (including the most sensitive item), the processing circuit 350 continues to perform CP operation on another die (or a third die) of the wafer WTT to be tested until the test of all the dies is completed.

By using the optimized test sequence of the CP operation generated by the machine learning model ML, when the processing circuit 350 performs the CP operation on each die, the most sensitive items are placed at the front. Therefore, the processing circuit 350 can immediately detect abnormal dies, reduce the test time, improve the production efficiency of the test line, and provides better price competitiveness.

Test methods, or certain aspects or portions thereof, may take the form of a program code (i.e., executable instructions) embodied in tangible media, such as floppy diskettes, CD-ROMS, hard drives, or any other machine-readable storage medium, wherein, when the program code is loaded into and executed by a machine such as a computer, the machine thereby becomes a test testing sequence for practicing the methods. The methods may also be embodied in the form of a program code transmitted over some transmission medium, such as electrical wiring or cabling, through fiber optics, or via any other form of transmission, wherein, when the program code is received and loaded into and executed by a machine such as a computer, the machine becomes a test testing sequence for practicing the disclosed methods. When implemented on a general-purpose processor, the program code combines with the processor to provide a unique apparatus that operates analogously to application-specific logic circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will be understood that although the terms “first,” “second,” etc. may be used herein to describe various elements, these elements should not be limited by these terms. These terms are only used to distinguish one element from another.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

What is claimed is:

1. A test equipment, comprising:
a first storage circuit storing a machine learning model;
an input-output interface receiving a plurality of wafer acceptance test (WAT) sample data and a plurality of chip probing (CP) sample data; and
a calculation circuit accessing the first storage circuit to load the machine learning model,
wherein:
in a training period:
the calculation circuit provides the plurality of WAT sample data and the plurality of CP sample data to the machine learning model,
the machine learning model calculates the plurality of WAT sample data and the plurality of CP sample data to generate a correlation,
in a test period:
the input-output interface receives product information and WAT measurement data,
the calculation circuit inputs the product information and the WAT measurement data to the machine learning model,
the machine learning model adjusts a testing sequence of a plurality of test items in a CP operation according to the correlation.

2. The test equipment as claimed in claim 1, further comprising:
a second storage circuit storing a program code; and
a processing circuit executing the program code in the test period to perform the CP operation on each die of a wafer to be tested.

3. The test equipment as claimed in claim 2, wherein in the training period, the machine learning model converts the testing sequence into the program code and writes the program code into the second storage circuit.

4. The test equipment as claimed in claim 3, wherein in response to a first die of the wafer to be tested failing to pass a specific item of the plurality of test items, the processing circuit stops performing the CP operation on the first die and marks the first die.

5. The test equipment as claimed in claim 4, wherein after marking the first die, the processing circuit performs the CP operation on a second die of the wafer to be tested.

6. The test equipment as claimed in claim 5, wherein in response to the second die passing the plurality of test items, the processing circuit performs the CP operation on a third die of the wafer to be tested.

7. The test equipment as claimed in claim 1, wherein the processing circuit performs the CP operation on each of a plurality of sample wafers to generate the plurality of CP sample data.

8. The test equipment as claimed in claim 7, wherein:
the machine learning model determines a failed test item from the CP sample data, and then determines a key parameter related to the failed test item from the WAT sample data, and
the machine learning model establishes the correlation according to the failed test item and the key parameter.

9. The test equipment as claimed in claim 8, wherein in response to the WAT measurement data having the key parameter and the key parameter not being within a normal range, the machine learning model adjusts the testing sequence of the plurality of test items in the CP operation according to the correlation.

10. The test equipment as claimed in claim 9, wherein the machine learning model determines at least one test item required for the wafer to be tested from the plurality of test items in the CP operation according to the product information.

11. A test method, comprising:
in a training period:
receiving a plurality of WAT sample data from a plurality of sample wafers;
performing a CP operation on the sample wafers to generate a plurality of CP sample data;
inputting the plurality of WAT sample data and the plurality of CP sample data into a machine learning model, wherein the machine learning model calculates the plurality of WAT sample data and the plurality of CP sample data to generate a correlation,
in a test period:
inputting product information and WAT measurement data of a wafer to be tested to the machine learning model,
wherein:
the machine learning model determines at least one key parameter from the WAT measurement data according to the correlation,
the machine learning model adjusts a testing sequence of a plurality of test items according to the key parameter, and
the wafer to be tested is tested according to the adjusted testing sequence of the plurality of test items.

12. The test method as claimed in claim 11, wherein each of the plurality of CP sample data is test results of all dies on each sample wafer.

13. The test method as claimed in claim 11, wherein each of the plurality of CP sample data has at least one of map data and a data-log.

14. The test method as claimed in claim 11, further comprising:
in the test period:
in response to a first die among the plurality of dies of the wafer to be tested not passing one of the plurality of test items, the remaining test items for the first die are stopped and the first die is marked.

15. The test method as claimed in claim 14, further comprising:
after marking the first die, performing the plurality of test items on a second die among the plurality of dies of the wafer to be tested.

16. The test method as claimed in claim 15, further comprising:
in response to the second die passing the plurality of test items of the CP operation, a third die among the plurality of dies of the wafer to be tested is tested.

17. The test method as claimed in claim 11, wherein the machine learning model determines a failed test item from the plurality of CP sample data, the failed test item is related to the key parameter, and the machine learning model establishes the correlation according to the failed test item and the key parameter.

18. The test method as claimed in claim 17, wherein in response to the WAT measurement data having the key parameter and the key parameter not being in a normal range, the machine learning model adjusts the testing sequence of the plurality of test items in the CP operation according to the correlation.

19. The test method as claimed in claim 18, wherein the machine learning model determines at least one test item required for the wafer to be tested from the test items in the CP operation according to the product information.

20. A computer readable storage media storing a program code, wherein in response to the program code being executed by a test equipment, the program code directs the test equipment to perform steps comprising:
in a training period:
receiving a plurality of WAT sample data from a plurality of sample wafers;
performing a CP operation on the sample wafers to generate a plurality of CP sample data; and
inputting the plurality of WAT sample data and the plurality of CP sample data into a machine learning model, wherein the machine learning model calculates the plurality of WAT sample data and the plurality of CP sample data to generate a correlation, and
in a test period:
inputting product information and WAT measurement data of a wafer to be tested to the machine learning model,
wherein:
the machine learning model determines at least one key parameter from the WAT measurement data according to the correlation,
the machine learning model adjusts a testing sequence of a plurality of test items according to the key parameter, and
the wafer to be tested is tested according to the adjusted testing sequence of the plurality of test items.
